(19) United States
(12) Patent Application Publication
(10) Pub. No.: US 2011/0290540 A1
(43) Pub. Date: Dec. 1, 2011

(54) Embedded printed circuit board and method of manufacturing the same

(75) Inventors: Hyungmi Jung, Suwon-si (KR); Jaechoon Cho, Suwon-si (KR); Choonkeun Lee, Suwon-si (KR); Taesung Jeong, Hwaseong-si (KR); Seungeun Lee, Seongnam-si (KR); Jinsun Park, Seoul (KR); Yeena Shin, Seoul (KR)

(73) Assignee: SAMSUNG ELECTRO-MECHANICS CO., LTD., Suwon (KR)

(21) Appl. No.: 13/064,986

(22) Filed: Apr. 29, 2011

(30) Foreign Application Priority Data
May 25, 2010 (KR) 10-2010-0048647
Sep. 14, 2010 (KR) 10-2010-0089951

(51) Int. Cl. H05K 1/03; B32B 38/00; H05K 1/02; B32B 38/10; H05K 3/30; B32B 37/02; B32B 38/08

(52) U.S. Cl. 174/255; 156/280; 29/832; 174/258

(57) ABSTRACT

Disclosed herein are an embedded printed circuit board and a method of manufacturing the same. The embedded printed circuit board includes: an insulating layer on which a cavity is formed; a chip mounted on the cavity; and a circuit layer formed on the insulating layer, wherein the insulating layer is made of photosensitive compositions including photosensitive monomer and photoinitiator. As a result, the cavity can be formed by selectively using only the insulating layer, thereby making it possible to secure a degree of freedom in the design of the embedded printed circuit board.

### CROSS REFERENCE TO RELATED APPLICATION

This application claims the benefit under 35 U.S.C. Section 119 of Korean Patent Application Nos. 10-2010-0048647, filed on May 25, 2010 and 10-2010-0089951, filed on Sep. 14, 2010, entitled “Embedded Printed Circuit Board And Method Of Manufacturing The Same”, which is hereby incorporated by reference in its entirety into this application.

### BACKGROUND OF THE INVENTION

1. Technical Field

The present invention relates to an embedded printed circuit board and a method of manufacturing the same, and more particularly, to an embedded printed circuit board and a method of manufacturing the same capable of forming a cavity for embedding a chip on a photosensitive film by an exposure and development process.

2. Description of the Related Art

With the development of the electronic industry, a demand for high-functional and small-sized electronic parts is increasing. In particular, a printed circuit board is getting slimmer in order to meet market needs for easy portability of mobile communication terminals such as a cellular phone, a PDA, etc. Further, attempts to provide more functions to the mobile communication terminals having a limited area have been continuously made. Therefore, development of a board capable of embedding electronic parts using a next-generation multi-functional/small package technology has been in the limelight.

A chip embedding process according to the related art has used a process of forming a cavity and taping it in order to fix a chip.

In this case, the cavity is formed by a method such as a mechanical drill, a punch, a laser drill, etc.

As described above, a single element embedding method generally embeds the chip by using the process of forming the cavity in order to embed the chip and performing the taping process on the lower portion of the board on which the cavity is formed in order to fix the chip.

However, the method using the mechanical drill, the punch, the laser drill, etc., does not form the cavity to accurately conform to the chip size due to a limitation in mechanical tolerance, thereby leading to a problem of forming the cavity larger than the chip and filling the remaining portion of the cavity.

In addition, in the case of the general CO2 laser, the cavities are formed in such a manner that each portion to be machined is machined to be points and the points are connected with each other, such that there is a problem in that it takes a significant amount of time in terms of the machining time as well as the process costs are also increased.

### SUMMARY OF THE INVENTION

An object of the present invention provides an embedded printed circuit board and a method of manufacturing the same capable of forming a cavity for embedding a chip on an insulating layer configured of a photosensitive film by an exposure and development process.

According to an exemplary embodiment of the present invention, there is provided an embedded printed circuit board, including: an insulating layer on which a cavity is formed; a chip mounted on the cavity; and a circuit layer formed on the insulating layer, wherein the insulating layer is made of photosensitive compositions including photosensitive monomer and photoinitiator.

The cavity may be formed by an exposure and development process.

The insulating layer may include resin compositions including composite epoxy resin including naphthalene based epoxy resin and rubber modified epoxy resin, curing agent, curing accelerator, and inorganic filler.

The curing agent may be at least any one compound selected from a group consisting of phenol novolac, bisphenol novolac, and a mixture thereof.

The curing accelerator may be imidazole based compound and is at least any one compound selected from a group consisting of 2-methyl imidazole, 1-(2-cyanoethyl)-2-alkyl imidazole, 2-phenyl imidazole, and a mixture thereof.

The inorganic filler may be at least any one inorganic selected from a group consisting of graphite, carbonblack, silica, and clay.

The photosensitive monomer may include acrylate resin.

According to another exemplary embodiment of the present invention, there is provided a method of manufacturing an embedded printed circuit board, including: forming an insulating layer including photosensitive compositions; forming a cavity on the insulating layer by performing an exposure and development process; disposing a chip in a cavity; and forming a plating layer on the insulating layer on which the chip is disposed and forming a pattern by etching the plating layer.

The form of the insulating layer may be any one of an RCC form, a build up film form, and a CCL form.

The insulating layer may be made of photosensitive compositions including photosensitive monomer and photoinitiator.

The insulating layer may include resin compositions including composite epoxy resin including naphthalene based epoxy resin and rubber modified epoxy resin, curing agent, curing accelerator, and inorganic filler.

The curing agent may be at least any one compound selected from a group consisting of phenol novolac, bisphenol novolac, and a mixture thereof.

The curing accelerator may be imidazole based compound and is at least any one compound selected from a group consisting of 2-methyl imidazole, 1-(2-cyanoethyl)-2-alkyl imidazole, 2-phenyl imidazole, and a mixture thereof.

The inorganic filler may be at least any one inorganic selected from a group consisting of graphite, carbonblack, silica, and clay.

The photosensitive monomer may include acrylate resin.

According to another exemplary embodiment of the present invention, there is provided an embedded printed circuit board, including: a core layer on which a cavity is formed; a copper clad layer of which the upper portion is applied with an adhesive layer for fixing a chip; a chip mounted in the cavity of the core layer disposed on the upper portion of the copper clad layer applied with the adhesive layer; an insulating layer formed between the cavity and the chip and on the upper portion of the core layer; and a circuit layer formed on the insulating layer, wherein the core layer is made of a photosensitive composition including a photosensitive monomer and an photoinitiator.

The cavity may be formed through the exposure and development processes.

Further, the core layer may include resin compositions including composite epoxy resin including naphthalene based epoxy resin and rubber modified epoxy resin, curing agent, curing accelerator, and inorganic filler.

In addition, the curing agent may be at least any one compound selected from a group consisting of phenol novolac, bisphenol novolac, and a mixture thereof.

In addition, the curing accelerator may be imidazole based compound and may be at least any one compound selected from a group consisting of 2-methyl imidazole, 1-(2-cyanoethyl)-2-alkyl imidazole, 2-phenyl imidazole, and a mixture thereof.

In addition, the inorganic filler may be at least any one inorganic material selected from a group consisting of graphite, carbonblack, silica, and clay.

In addition, the photosensitive monomer may include acrylate resin.

According to another exemplary embodiment of the present invention, there is provided an embedded printed circuit board, including: a core layer on which a cavity is formed; a copper clad layer of which the upper portion is applied with an adhesive layer for fixing a chip; a chip mounted in the cavity of the core layer disposed on the upper portion of the copper clad applied with the adhesive layer; an insulating layer formed between the cavity and the chip and on the upper portion of the core layer; a via hole formed on the insulating layer; and a circuit layer formed on the insulating layer, wherein the core layer and the insulating layer is made of a photosensitive composition including a photosensitive monomer and an photoinitiator.

The cavity may be formed through the exposure and development processes.

In addition, the via hole may be formed on the insulating layer by forming the pattern through the exposure and development processes to open a pad of the chip.

Further, the core layer and the insulating layer may include resin compositions including composite epoxy resin including naphthalene based epoxy resin and rubber modified epoxy resin, curing agent, curing accelerator, and inorganic filler.

In addition, the curing agent may be at least any one compound selected from a group consisting of phenol novolac, bisphenol novolac, and a mixture thereof.

In addition, the curing accelerator may be imidazole based compound and may be at least any one compound selected from a group consisting of 2-methyl imidazole, 1-(2-cyanoethyl)-2-alkyl imidazole, 2-phenyl imidazole, and a mixture thereof.

In addition, the inorganic filler may be at least any one inorganic material selected from a group consisting of graphite, carbonblack, silica, and clay.

In addition, the photosensitive monomer may include acrylate resin. According to another exemplary embodiment of the present invention, there is provided an embedded printed circuit board, including: a core layer on which a cavity is formed; a copper clad layer of which the upper portion is applied with an adhesive layer for fixing a chip; a chip mounted in the cavity of the core layer disposed on the upper portion of the copper clad applied with the adhesive layer; an insulating layer formed between the cavity and the chip and on the upper portion of the core layer; and a circuit layer formed on the insulating layer, wherein the core layer is made of a photosensitive composition and the chip has a pad of the chip disposed to be bonded to the adhesive layer on the copper clad layer.

The cavity may be formed through the exposure and development processes.

Further, the core layer may include resin compositions including composite epoxy resin including naphthalene based epoxy resin and rubber modified epoxy resin, curing agent, curing accelerator, and inorganic filler.

In addition, the curing agent may be at least any one compound selected from a group consisting of phenol novolac, bisphenol novolac, and a mixture thereof.

In addition, the curing accelerator may be imidazole based compound and may be at least any one compound selected from a group consisting of 2-methyl imidazole, 1-(2-cyanoethyl)-2-alkyl imidazole, 2-phenyl imidazole, and a mixture thereof.

In addition, the inorganic filler may be at least any one inorganic material selected from a group consisting of graphite, carbonblack, silica, and clay.

In addition, the photosensitive monomer may include acrylate resin.

According to another exemplary embodiment of the present invention, there is provided a method of manufacturing an embedded printed circuit board, including: providing a core layer including a photosensitive composition; forming a cavity on the core layer by exposure and development processes; disposing a chip on a copper clad applied with an adhesive layer; laminating the core layer on the copper clad layer applied with an adhesive layer to mount the chip in the cavity of the core layer; forming an insulating layer on the core layer mounted with the chip; and laminating the copper clad layer on the insulating layer and forming a circuit pattern on the copper clad layer.

According to another exemplary embodiment of the present invention, there is provided a method of manufacturing an embedded printed circuit board, including: providing a core layer including a photosensitive composition; forming a cavity on the core layer by exposure and development processes; disposing a chip on a copper clad applied with an adhesive layer; laminating the core layer on the copper clad layer applied with an adhesive layer to mount the chip in the cavity of the core layer; forming an insulating layer made of a photosensitive composition on the core layer mounted with the chip; forming a via hole on the insulating layer to open a pad of the chip by forming a pattern through the exposure and development processes; and laminating the copper clad layer on the insulating layer and forming a circuit pattern on the copper clad layer.

According to another exemplary embodiment of the present invention, there is provided a method of manufacturing an embedded printed circuit board, including: providing a core layer including a photosensitive composition; forming a cavity on the core layer by exposure and development processes; disposing a chip to attach the pad of the chip to an adhesive layer applied with a copper clad; laminating the core layer on the copper clad layer applied with an adhesive layer to mount the chip in the cavity of the core layer; forming an insulating layer on the core layer mounted with the chip; and laminating the copper clad layer on the insulating layer and forming a circuit pattern on the copper clad layer.

### BRIEF DESCRIPTION OF THE DRAWINGS

FIGS. 1 to 5 are cross-sectional views showing an embedded printed circuit board according to a first exemplary embodiment of the present invention;

FIGS. 6 to 11 are cross-sectional views showing an embedded printed circuit board according to a second exemplary embodiment of the present invention;

FIGS. 12 to 18 are cross-sectional views sequentially showing a method of manufacturing an embedded printed circuit board according to a third exemplary embodiment of the present invention;

FIGS. 19 to 21 are cross-sectional views sequentially showing a method of manufacturing an embedded printed circuit board according to a fourth exemplary embodiment of the present invention; and

FIGS. 22 to 26 are cross-sectional views sequentially showing a method of manufacturing an embedded printed circuit board according to a fifth exemplary embodiment of the present invention.

### DESCRIPTION OF THE PREFERRED EMBODIMENTS

Hereinafter, an embedded printed circuit board according to exemplary embodiments of the present invention will be described in detail with reference to the accompanying drawings. The exemplary embodiments of the present invention to be described below are provided by way of example so that the idea of the present invention can be sufficiently transferred to those skilled in the art to which the present invention pertains. Therefore, the present invention may be modified in many different forms and it should not be limited to the embodiments set forth herein. In the drawings, the size, and the thickness of the device may be exaggerated for convenience. Like reference numerals denote like elements throughout the specification.

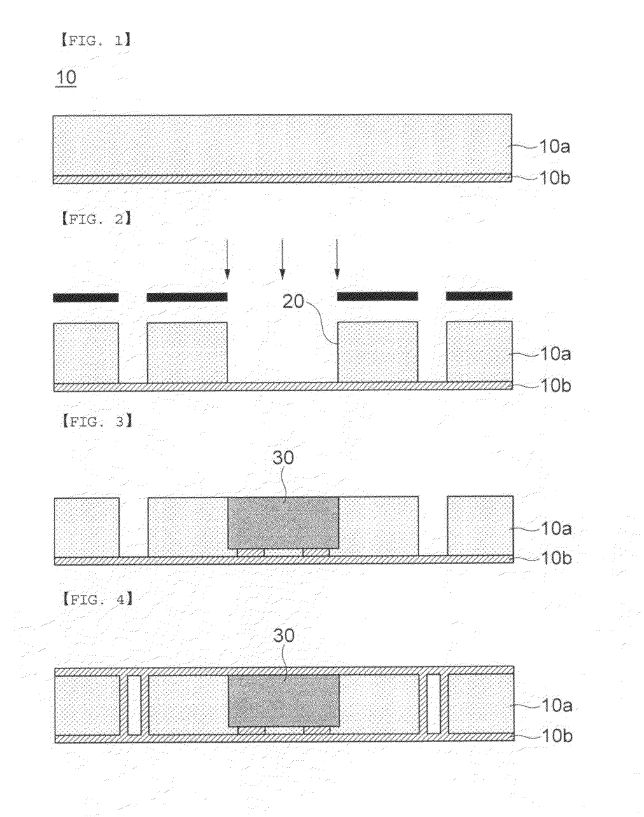

FIGS. 1 to 5 are cross-sectional views showing an embedded printed circuit board according to a first exemplary embodiment of the present invention.

Referring to FIGS. 1 to 5, an embedded printed circuit board according to the present invention may include an insulating layer 10a on which a cavity 20 is formed, a cavity 20, a chip 30 mounted on the cavity, and a circuit layer 40 formed on the insulating layer.

More specifically, the insulating layer 10a may be made of photosensitive compositions, wherein the insulating layer 10a is stacked on a copper foil layer 10b, thereby forming a resin coated copper (RCC) 10. In this configuration, the insulating layer 10a may be made of photosensitive monomer and photosensitive compositions including a photoinitiator. This may be advantageous in forming the cavity because degradation in physical properties of the existing thermosetting type of insulating materials can be minimized when the photosensitive monomer and the photoinitiator is added to the existing thermosetting type of insulating material compositions to be UV cured.

Meanwhile, the insulating layer may include resin compositions including composite epoxy resin including naphthalene based epoxy resin and rubber modified epoxy resin, curing agent, curing accelerator, and inorganic filler.

The composite epoxy resin may include the naphthalene based epoxy resin of 100 to 300 equivalent of an average epoxy resin and the rubber modified epoxy resin of 100 to 500 equivalent of an average epoxy resin. Further, a mixture of 50 to 70 parts by weight of the naphthalene based epoxy resin and 1 to 30 parts by weight of the rubber modified epoxy resin for every 100 parts by weight of the composite epoxy resin can be used.

The curing agent may be at least any one compound selected from a group consisting of phenol novolac, bisphenol novolac, and a mixture thereof. The curing accelerator is imidazole based compound and may be at least any one compound selected from a group consisting of 2-methyl imidazole, 1-(2-cyanoethyl)-2-alkyl imidazole, 2-phenyl imidazole, and a mixture thereof. In this case, it is preferable that the curing accelerator is mixed at 0.1 to 1 parts by weight for every 100 parts by weight of the composite epoxy resin.

Meanwhile, it is preferable that the photosensitive monomer should have both a double bond and —COOH group in a chemical structure and includes acrylate resin. In this case, the photosensitive monomer may include the photoinitiator of 1 to 10 wt %.

In addition, the inorganic filler may be at least any one inorganic material selected from a group consisting of graphite, carbonblack, silica, and clay. In this case, it is preferable that the inorganic filler is mixed at 10 to 60 parts by weight for every 100 parts by weight of the composite epoxy resin, is surface-treated with silane coupling agent, and includes spherical fillers having a different size, but is not limited thereto.

The compositions prepared as described above may be prepared in a film form by casting the prepared compositions on a PET substrate at 50 to 120 μm using a film casting process.

As shown in FIG. 2, the cavity 20 may be formed on the insulating layer 10a by performing an exposure and development process.

More specifically, the prepared film may be laminated on the upper portion of an electrode by applying a pressure of 0.7 to 7.5 kgf at 80° C. for 1 minute and then, dried according to the predetermined temperature and time. In this case, the drying is performed at the dryness that does not stick a barrier material layer to a working film at the time of performing the contact exposure and when the drying process completes, it is preferable to perform the exposure at a cumulative amount of 150 mj to 1000 mj by using a contact exposure device.

In addition, after the exposure is performed, the thermosetting is partially performed through a pre-cure process. Finally, after the development is primarily performed by applying 1 wt % Na2CO3 developer at a speed of 1 m/min, it is completed by performing ultrasonic cleaning for a predetermined time by using an organic solvent (for example, 2-methoxy ethanol) capable of melting epoxy. When development is completed, the cavity 20 may be formed by performing post-curing at about 190° C.

Since the method of forming the pattern of the photosensitive film uses UV curing, exposure, and development, it has a smaller tolerance than the mechanical processing method and can form the cavity similar to the chip size. Therefore, it is advantageous in the chip placing and does not need a separate adhesive member in the post-process step.

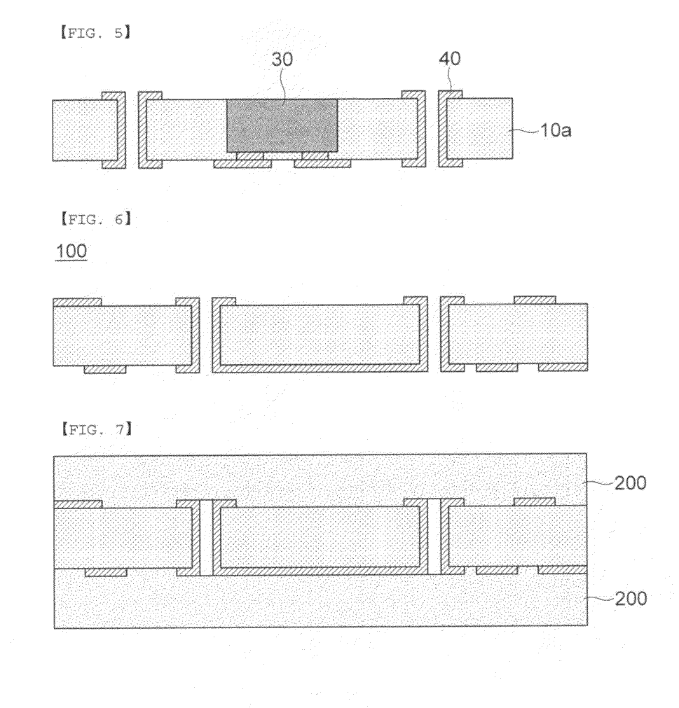

Thereafter, as shown in FIGS. 3 to 5, the chip 30 is disposed in the cavity 20 and is electrically connected by performing the build up film curing and the Cu plating and a circuit 40 may be formed by performing Cu patterning.

Herein, the chip 30 may be an active device, a passive device, or an IC.

The form of the insulating layer disclosed in the present invention may be any one of a resin coating copper clad laminate (RCC) form where the copper clad is stacked only on one of the insulating material, a build up film form, and a double-sided copper clad laminate (CCL) form.

For convenience of explanation, the detailed description of the overlapping technology with the technologies disclosed in FIGS. 1 to 5 will be omitted below.

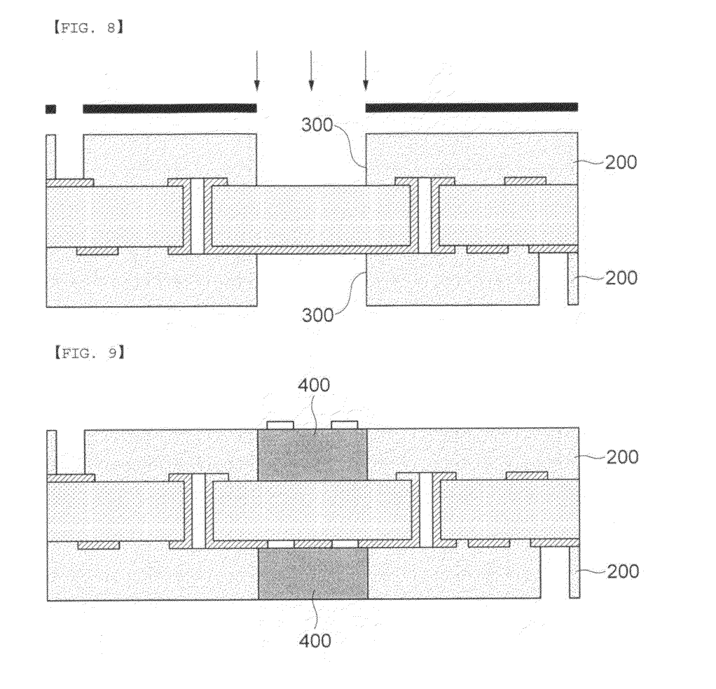

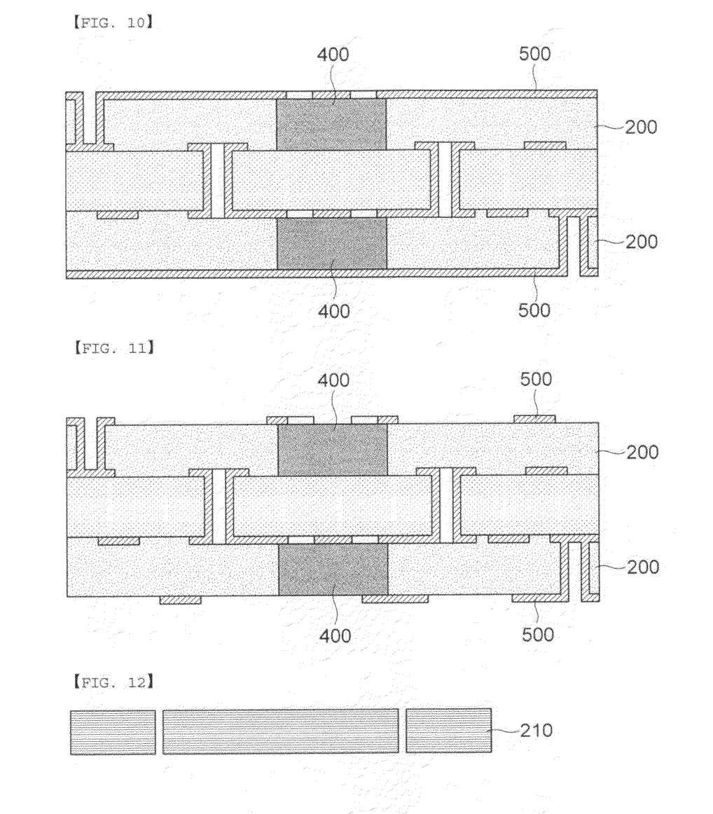

FIGS. 6 to 11 are cross-sectional views showing an embedded printed circuit board according to a second exemplary embodiment of the present invention and show an example where the second exemplary embodiment is applied to a multi-layer printed circuit board.

As shown, the embedded printed circuit board may include a core layer 110, an insulating layer 120, a cavity 130, a chip 140, and a circuit layer 150, all of which are included in the copper clad laminate (CCL) form.

More specifically, the insulating layer 120 formed of the photosensitive buildup film is stacked on the upper and lower portions of the core layer 110 and the cavity 130 and a connecting via Via may be formed on the insulating layer 120 by performing the exposure and development process. In this case, the photosensitive buildup film is the same as the manufacturing method shown in FIGS. 1 to 5 and therefore, the detailed description thereof will be omitted.

Thereafter, after the chip 140 is disposed in the cavity 130, the electrode layer may be formed by performing the buildup film curing and the Cu plating and the electrode pattern 150 may be formed by performing the patterning.

The method of manufacturing the embedded printed circuit board according to the exemplary embodiment of the present invention will now be described with reference to FIGS. 1 to 5.

FIGS. 1 to 5 are cross-section views sequentially showing a process for explaining the method of manufacturing the embedded printed circuit board according to the exemplary embodiment of the present invention.

First, as shown in FIG. 1, the insulating layer 10a including the photosensitive compositions is provided.

In this configuration, the insulating layer 10a may be made of photosensitive monomer and photosensitive compositions including a photoinitiator. In this case, the insulating layer may include resin compositions including composite epoxy resin including naphthalene based epoxy resin and rubber modified epoxy resin, curing agent, curing accelerator, and inorganic filler.

Thereafter, as shown in FIG. 2, the cavity 20 may be formed on the insulating layer 10a by performing the exposure and development process.

More specifically, the prepared film may be laminated on the upper portion of an electrode by applying a pressure of 0.7 to 7.5 kgf at 80° C. for 1 minute and then, dried according to the predetermined temperature and time. In this case, the drying is performed at the dryness that does not stick a barrier material layer to a working film at the time of performing contact exposure and when the drying process completes, it is preferable to perform exposure at a cumulative amount of 150 mj to 1000 mj by using a contact exposure device.

In addition, after exposure is performed, thermosetting is partially performed through a pre-cure process. Finally, after development is primarily performed by applying 1 wt % Na2CO3 developer at a speed of 1 m/min, it is completed by performing ultrasonic cleaning for a predetermined time by using an organic solvent (for example, 2-methoxy ethanol) capable of melting epoxy. When development is completed, the cavity 20 may be formed by performing post-curing at about 190° C.

Thereafter, as shown in FIG. 3, the chip 30 may be disposed in the cavity 20. Herein, the chip 30 may be an active device, a passive device, or an IC.

Next, as shown in FIGS. 4 and 5, a plating layer may be formed on the insulating layer 10a on which the chip 30 is disposed and the pattern may be formed by etching the plating layer.

Herein, the known method may be generally applied to the plating layer. For example, after the through hole is formed, the known desmear process, plasma process, etc., may be performed and the electroless copper plating and the electric copper plate may be performed. Thereafter, external circuits are formed on the surface and a precious metal plating resistor is finally formed in order to prevent oxidation, and nickel plating and gold plating may be performed. The plating layer may be electrically connected to the electrode of the electric element.

FIGS. 12 to 18 are cross-sectional views sequentially showing a method of manufacturing an embedded printed circuit board according to a third exemplary embodiment of the present invention. The case where the core layer is made of a photosensitive material will be described by way of example.

As shown, the embedded printed circuit board 200 may include a core layer 210 on which a cavity is formed; a copper clad layer 230 of which the upper portion is applied with an adhesive layer 240 for fixing a chip 250; a chip 250 mounted in the cavity of the core layer 210 disposed on the upper portion of the copper clad layer 230 applied with the adhesive layer 240; an insulating layer 260 formed between the cavity 220 and the chip 250 and on the upper portion of the core layer 210; and a circuit layer 270 formed on the insulating layer 260.

Herein, the core layer 210 may be made of a photosensitive composition.

The core layer 210 may be made of a photosensitive compositions including a photosensitive monomer and a photoinitiator. This may be advantageous in forming the cavity because degradation in physical properties of the existing thermosetting type of insulating materials can be minimized when the photosensitive monomer and the photoinitiator are added to the existing thermosetting type of insulating material compositions to be UV cured.

Meanwhile, the core layer may include resin compositions' including composite epoxy resin including naphthalene based epoxy resin and rubber modified epoxy resin, curing agent, curing accelerator, and inorganic filler.

The composite epoxy resin may include the naphthalene based epoxy resin of 100 to 300 equivalent of an average epoxy resin and the rubber modified epoxy resin of 100 to 500 equivalent of an average epoxy resin. Further, a mixture of 50 to 70 parts by weight of the naphthalene based epoxy resin and 1 to 30 parts by weight of the rubber modified epoxy resin for every 100 parts by weight of the composite epoxy resin can be used.

The curing agent may be at least any one compound selected from a group consisting of phenol novolac, bisphenol novolac, and a mixture thereof. The curing accelerator is imidazole based compound and may be at least any one compound selected from a group consisting of 2-methyl imidazole, 1-(2-cyanoethyl)-2-alkyl imidazole, 2-phenyl imidazole, and a mixture thereof. In this case, it is preferable that the curing accelerator is mixed at 0.1 to 1 parts by weight for every 100 parts by weight of the composite epoxy resin.

Meanwhile, it is preferable that the photosensitive monomer should have both a double bond and —COOH group in a chemical structure and includes acrylate resin. In this case, the photosensitive monomer may include the photoinitiator of 1 to 10 wt %.

In addition, the inorganic filler may be at least any one inorganic material selected from a group consisting of graphite, carbonblack, silica, and clay. In this case, it is preferable that the inorganic filler is mixed at 10 to 60 parts by weight for every 100 parts by weight of the composite epoxy resin, is surface-treated with silane coupling agent, and includes spherical fillers having a different size, but is not limited thereto.

The compositions prepared as described above may be prepared in a film form by casting the prepared compositions on a PET substrate at 50 to 120 μm using a film casting process.

In addition, the cavity 220 may be formed through the exposure and development processes.

For example, when the core layer 210 is applied as the photosensitive material, the film having a disc size forms an exposure mark by using the CNC drill and the process such as exposure, development, dry, curing, etc., may be progressed according to a line, which can shorten time several tens times higher than the method of forming of a cavity by the CO2 laser machining.

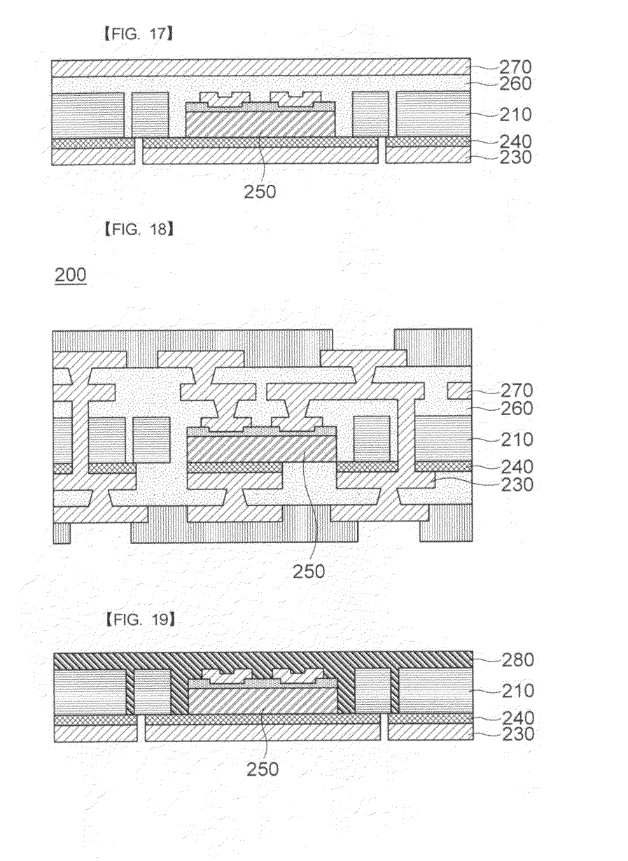

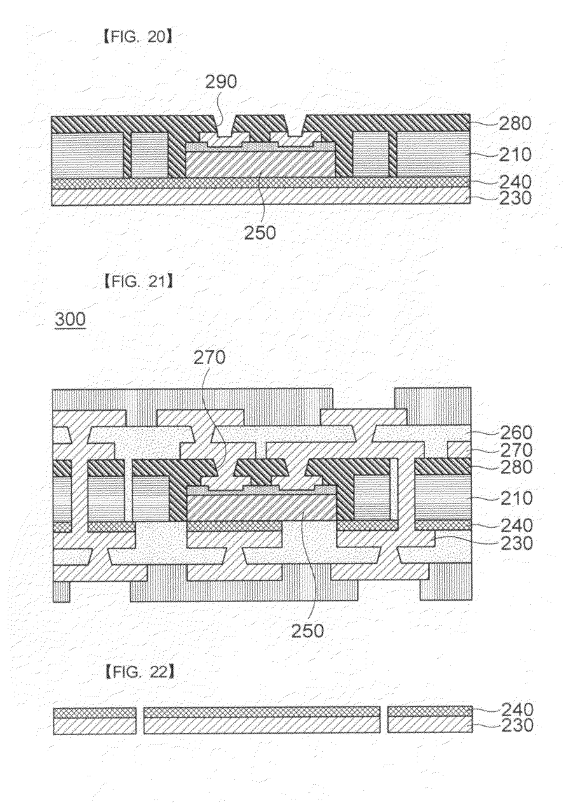

FIGS. 19 to 21 are cross-sectional views sequentially showing a method of manufacturing an embedded printed circuit board according to a fourth exemplary embodiment of the present invention. The case where the core layer and the insulating layer are made of a photosensitive material will be described by way of example.

The embedded printed circuit board of FIGS. 19 to 21 performs the same process as FIGS. 12 to 16 before performing the process of FIG. 19 and therefore, the drawings thereof are not separately shown.

In addition, among the materials of the above-mentioned third exemplary embodiment, the material of the core layer and the insulating layer disclosed in the fourth exemplary embodiment of the embedded printed circuit board may be optionally applied.

As shown, the embedded printed circuit board 300 may include a core layer 210 on which a cavity 220 is formed; a copper clad layer 230 of which the upper portion is applied with an adhesive layer 240 for fixing a chip 250; a chip 250 mounted in the cavity 220 of the core layer 210 disposed on the upper portion of the copper clad layer 230 applied with the adhesive layer 240; an insulating layer 280 formed between the cavity 220 and the chip 250 and on the upper portion of the core layer 210; a via hole 290 formed on the insulating layer 280; and a circuit layer formed on the insulating 280.

Herein, the core layer 210 and the insulating layer 280 may be made of a photosensitive composition.

The insulating layer 280 may be made of the same material as the photosensitive composition applied to the core layer 210 shown in FIGS. 12 to 18. The detailed description thereof will be omitted.

In addition, the cavity 220 may be formed through the exposure and development processes.

Further, the via hole 290 may be formed on the insulating layer 280 to open the pad of the chip 250 by forming a pattern through the exposure and development processes.

For example, similar to the method of forming the cavity 220, a portion where the via hole will be formed is subjected to the exposure, development, and curing processes through the mask, such that the via hole 290 is opened.

FIGS. 22 to 26 are cross-sectional views sequentially showing a method of manufacturing an embedded printed circuit board according to a fifth exemplary embodiment of the present invention. The case where the core layer is made of a photosensitive material and the pad of the chip is disposed to contact the adhesive layer will be described by way of example.

The embedded printed circuit board of FIGS. 22 to 26 performs the same process as FIGS. 12 to 14 before performing the process of FIG. 22 and therefore, the drawings thereof are not separately shown.

As shown, the embedded printed circuit board 400 may include a core layer 210 on which a cavity 220 is formed; a copper clad layer 230 of which the upper portion is applied with an adhesive layer 240 for fixing a chip 310; a chip 310 mounted in the cavity of the core layer disposed on the upper portion of the copper clad layer 230 applied with the adhesive layer 240; an insulating layer 320 formed between the cavity 220 and the chip 310 and on the upper portion of the core layer 210; and a circuit layer formed on the insulating layer 320.

In this case, the core layer 210 may be made of a photosensitive composition and the chip 310 may be disposed so that the pad of the chip 310 is bonded to the adhesive layer 240 on the copper clad layer.

In addition, the cavity 220 may be formed through the exposure and development processes.

Hereinafter, the method of manufacturing the embedded printed circuit board will be described with reference to the above-mentioned drawings.

First, as shown in FIG. 12, the core layer 210 including the photosensitive compositions may be provided.

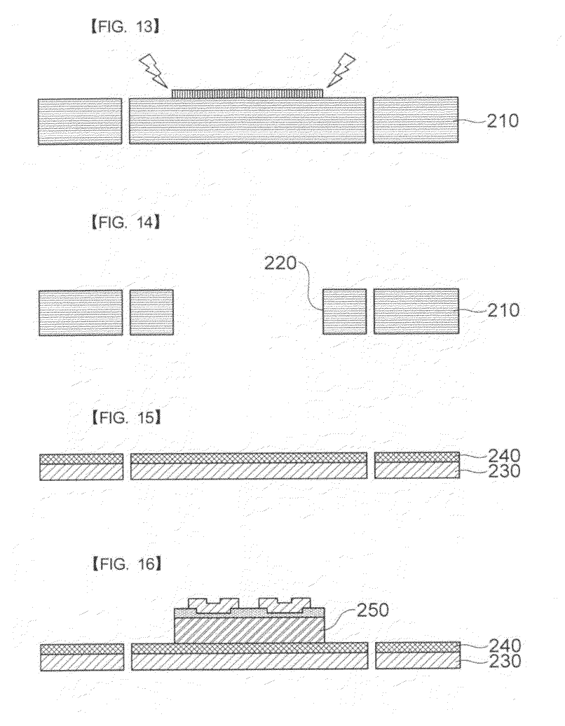

As shown in FIGS. 13 and 14, the cavity 220 may be formed on the core layer 210 by the exposure and development processes.

For example, the exposure mark is formed in the core layer 210 made of the photosensitive material by using the laser or the CNC drill and the cavity 220 is formed through the exposure and development processes.

As shown in FIGS. 15 and 16, the chip 250 may be disposed on the copper clad layer 230 applied with the adhesive layer 240.

As shown in FIG. 17, the core layer 210 may be laminated on the copper clad layer applied with the adhesive layer 240 to mount the chip 250 in the cavity 220 of the core layer 210.

For example, the core layer 210 formed through FIGS. 12 to 14 is laminated on the upper portion of the copper clad layer 230 applied with the adhesive layer formed through FIGS. 15 and 16. In this case, the chip 250 disposed on the copper clad layer 230 is laminated to be inserted into the cavity 220 formed on the core layer 210.

As shown in FIG. 17, the insulating layer 260 may be formed on the core layer 210 mounted with the chip 250.

As shown in FIGS. 17 and 18, the copper clad layer 230 may be laminated on the insulating layer 260 and the circuit pattern may be formed on the copper clad layer 230.

Thereafter, as shown in FIG. 18, it is also possible to form a multi-layer substrate.

Hereinafter, the method of manufacturing the embedded printed circuit board according to the fourth exemplary embodiment will be described with reference to FIGS. 12 to 16 and FIGS. 19 to 21.

First, as shown in FIG. 12, the core layer 210 including the photosensitive compositions may be provided.

As shown in FIGS. 13 and 14, the cavity 220 may be formed on the core layer 210 by the exposure and development processes.

For example, the exposure mark is formed in the core layer 210 made of the photosensitive material by using the laser or the CNC drill and the cavity 220 is formed through the exposure and development processes.

As shown in FIGS. 15 and 16, the chip 250 may be disposed on the copper clad layer 230 applied with the adhesive layer 240.

As shown in FIG. 19, the core layer 210 may be laminated on the copper clad layer 230 applied with the adhesive layer 240 to mount the chip 250 in the cavity 220 of the core layer 210.

Further, the insulating layer 280 made of the photosensitive composition may be formed on the core layer 210 mounted with the chip 250.

In this configuration, the insulating layer 280 may be formed between the cavity 220 and the chip 250 and on the upper portion of the core layer 210.

Further, the via hole 290 may be formed on the insulating layer 280 to open the pad of the chip 250 by forming a pattern through the exposure and development processes.

In addition, the copper clad layer is laminated on the insulating layer 280 and the circuit pattern may be formed on the copper clad layer.

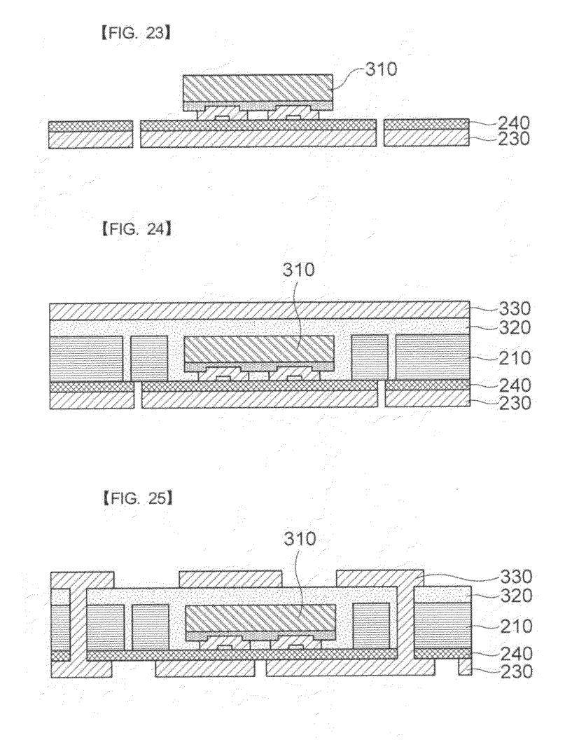

Thereafter, as shown in FIG. 21, it is also possible to form a multi-layer substrate.

Hereinafter, the method of manufacturing the embedded printed circuit board according to the fifth exemplary embodiment will be described with reference to FIGS. 12 to 14 and FIGS. 22 to 26.

In addition, among the materials of the above-mentioned third exemplary embodiment, the material of the core layer and the insulating layer disclosed in the fifth exemplary embodiment of the embedded printed circuit board may be optionally applied.

First, as shown in FIG. 12, the core layer 210 including the photosensitive compositions may be provided.

As shown in FIGS. 13 and 14, the cavity 220 may be formed on the core layer 210 by the exposure and development processes.

For example, the exposure mark is formed in the core layer 210 made of the photosensitive material by using the laser or the CNC drill and the cavity 220 is formed through the exposure and development processes.

As shown in FIGS. 22 and 23, the chip 310 may be disposed so that the pad of the chip 310 is attached to the adhesive layer 240 applied on the copper clad layer 230.

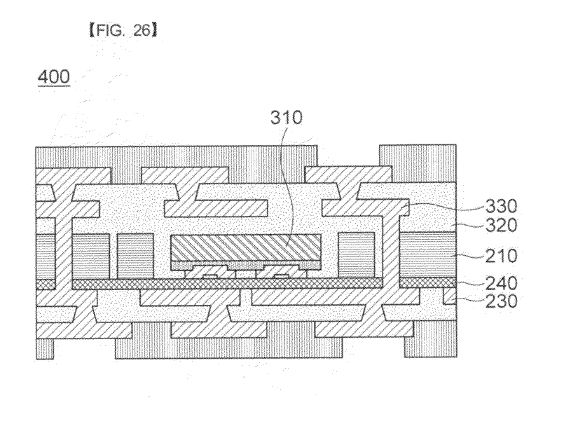

As shown in FIG. 24, the core layer 210 may be laminated on the copper clad layer 230 applied with the adhesive layer 240 to mount the chip 310 in the cavity 220 of the core layer 210.

Further, the insulating layer 320 may be formed on the core layer 210 mounted with the chip 310.

As shown in FIGS. 24 and 25, the copper clad layer 230 may be laminated on the insulating layer 320 and the circuit pattern may be formed on the copper clad layer 230.

In this case, after the copper clad layer 230 is laminated on the insulating layer 320, the circuit pattern may be formed through the etching, surface treatment, plating, circuit forming processes.

Thereafter, as shown in FIG. 26, it is also possible to form a multi-layer substrate.

The embedded printed circuit board and the method of manufacturing the same according to the present invention can easily form the cavity to which the photosensitive build up layer is applied while reducing tolerance, by performing the exposure and development process.

Further, the present invention forms the cavity by selectively using only the insulating layer at the time of manufacturing the embedded printed circuit board, such that the degree of freedom in a design of the embedded printed circuit board can be further increased as compared to the related art.

In addition, the present invention does not need a separate adhesive member at the time of performing the chip embedding process, thereby making it possible to save costs such as material cost and process cost.

In addition, the present invention applies the photosensitive film as the core materials to form the cavity by the exposure and development processes, thereby making it possible to reduce the process time and the process cost as compared to the method of machining the cavity by using laser.

Although the exemplary embodiments of the present invention have been disclosed for illustrative purposes, those skilled in the art will appreciate that various modifications, additions and substitutions are possible, without departing from the scope and spirit of the invention as disclosed in the accompanying claims. Accordingly, such modifications, additions and substitutions should also be understood as falling within the scope of the present invention.

What is claimed is:

1. An embedded printed circuit board, comprising:
an insulating layer on which a cavity is formed;
a chip mounted on the cavity; and
a circuit layer formed on the insulating layer,
wherein the insulating layer is made of photosensitive compositions including photosensitive monomer and photoinitiator.

2. The embedded printed circuit board according to claim 1, wherein the cavity is formed by an exposure and development process.

3. The embedded printed circuit board according to claim 1, wherein the insulating layer includes resin compositions including composite epoxy resin including naphthalene based epoxy resin and rubber modified epoxy resin, curing agent, curing accelerator, and inorganic filler.

4. The embedded printed circuit board according to claim 3, wherein the curing agent is at least any one compound selected from a group consisting of phenol novolac, bisphenol novolac, and a mixture thereof.

5. The embedded printed circuit board of claim 3, wherein the curing accelerator is imidazole based compound and is at least any one compound selected from a group consisting of 2-methyl imidazole, 1-(2-cyanoethyl)-2-alkyl imidazole, 2-phenyl imidazole, and a mixture thereof.

6. The embedded printed circuit board according to claim 3, wherein the inorganic filler is at least any one inorganic selected from a group consisting of graphite, carbonblack, silica, and clay.

7. The embedded printed circuit board according to claim 1, wherein the photosensitive monomer includes acrylate resin.

8. A method of manufacturing an embedded printed circuit board, comprising:
forming an insulating layer including photosensitive compositions;
forming a cavity on the insulating layer by performing an exposure and development process;
disposing a chip in a cavity; and
forming a plating layer on the insulating layer on which the chip is disposed and forming a pattern by etching the plating layer.

9. The method of manufacturing an embedded printed circuit board accordign to claim 8, wherein the form of the insulating layer is any one of an RCC form, a build up film form, and a CCL form.

10. The method of manufacturing an embedded printed circuit board accoridng to claim 8, wherein the insulating layer is made of photosensitive compositions including photosensitive monomer and photoinitiator.

11. The method of manufacturing an embedded printed circuit board according to claim 10, wherein the insulating layer includes resin compositions including composite epoxy resin including naphthalene based epoxy resin and rubber modified epoxy resin, curing agent, curing accelerator, and inorganic filler.

12. The method of manufacturing an embedded printed circuit board according to claim 11, wherein the curing agent is at least any one compound selected from a group consisting of phenol novolac, bisphenol novolac, and a mixture thereof.

13. The method of manufacturing an embedded printed circuit board according to claim 11, wherein the curing accelerator is imidazole based compound and is at least any one compound selected from a group consisting of 2-methyl imidazole, 1-(2-cyanoethyl)-2-alkyl imidazole, 2-phenyl imidazole, and a mixture thereof.

14. The method of manufacturing an embedded printed circuit board according to claim 11, wherein the inorganic filler is at least any one inorganic selected from a group consisting of graphite, carbonblack, silica, and clay.

15. The method of manufacturing an embedded printed circuit board according to claim 8, wherein the photosensitive monomer includes acrylate resin.

16. An embedded printed circuit board, comprising:
a core layer on which a cavity is formed;
a copper clad layer of which the upper portion is applied with an adhesive layer for fixing a chip;
a chip mounted in the cavity of the core layer disposed on the upper portion of the copper clad layer applied with the adhesive layer;
an insulating layer formed between the cavity and the chip and on the upper portion of the core layer; and
a circuit layer formed on the insulating layer,
wherein the core layer is made of a photosensitive composition including a photosensitive monomer and an photoinitiator.

17. The embedded printed circuit board according to claim 16, wherein the cavity is formed through the exposure and development processes

18. The embedded printed circuit board according to claim 16, wherein the core layer includes resin compositions including composite epoxy resin including naphthalene based epoxy resin and rubber modified epoxy resin, curing agent, curing accelerator, and inorganic filler.

19. The embedded printed circuit board according to claim 18, wherein the curing agent is at least any one compound selected from a group consisting of phenol novolac, bisphenol novolac, and a mixture thereof.

20. The embedded printed circuit board according to claim 18, wherein the curing accelerator is imidazole based compound and is at least any one compound selected from a group consisting of 2-methyl imidazole, 1-(2-cyanoethyl)-2-alkyl imidazole, 2-phenyl imidazole, and a mixture thereof.

21. The embedded printed circuit board according to claim 18, wherein the inorganic filler is at least any one inorganic material selected from a group consisting of graphite, carbonblack, silica, and clay.

22. The embedded printed circuit board according to claim 16, wherein the photosensitive monomer includes acrylate resin.

23. An embedded printed circuit board, comprising:
a core layer on which a cavity is formed;
a copper clad layer of which the upper portion is applied with an adhesive layer for fixing a chip;
a chip mounted in the cavity of the core layer disposed on the upper portion of the copper clad applied with the adhesive layer;
an insulating layer formed between the cavity and the chip and on the upper portion of the core layer;
a via hole formed on the insulating layer; and
a circuit layer formed on the insulating layer,
wherein the core layer and the insulating layer is made of a photosensitive composition including a photosensitive monomer and an photoinitiator.

24. The embedded printed circuit board according to claim 23, wherein the cavity is formed through the exposure and development processes.

25. The embedded printed circuit board according to claim 24, wherein the via hole is formed on the insulating layer to open a pad of the chip by forming the pattern through the exposure and development processes.

26. The embedded printed circuit board according to claim 23, wherein the core layer and the insulating layer includes resin compositions including composite epoxy resin including naphthalene based epoxy resin and rubber modified epoxy resin, curing agent, curing accelerator, and inorganic filler.

27. The embedded printed circuit board according to claim 26, wherein the curing agent is at least any one compound of a group selected from a group consisting of phenol novolac, bisphenol novolac, and a mixture thereof.

28. The embedded printed circuit board according to claim 26 wherein the curing accelerator is imidazole based compound and is at least any one compound selected from a group consisting of 2-methyl imidazole, 1-(2-cyanoethyl)-2-alkyl imidazole, 2-phenyl imidazole, and a mixture thereof.

29. The embedded printed circuit board according to claim 26, wherein the inorganic filler is at least any one inorganic material selected from a group consisting of graphite, carbonblack, silica, and clay.

30. The embedded printed circuit board according to claim 23, wherein the photosensitive monomer includes acrylate resin.

31. An embedded printed circuit board, comprising:
a core layer on which a cavity is formed;
a copper clad layer of which the upper portion is applied with an adhesive layer for fixing a chip;
a chip mounted in the cavity of the core layer disposed on the upper portion of the copper clad applied with the adhesive layer;
an insulating layer formed between the cavity and the chip and on the upper portion of the core layer; and
a circuit layer formed on the insulating layer, wherein the core layer is made of a photosensitive composition and the chip is disposed so that the pad of the chip is disposed to be bonded to the adhesive layer on the copper clad layer.

32. The embedded printed circuit board according to claim 31, wherein the cavity is formed through the exposure and development processes.

33. The embedded printed circuit board according to claim 32, wherein the core layer includes resin compositions including composite epoxy resin including naphthalene based epoxy resin and rubber modified epoxy resin, curing agent, curing accelerator, and inorganic filler.

34. The embedded printed circuit board according to claim 33, wherein the curing agent is at least any one compound of a group selected from a group consisting of phenol novolac, bisphenol novolac, and a mixture thereof.

35. The embedded printed circuit board according to claim 33, wherein the curing accelerator is imidazole based compound and is at least any one compound selected from a group consisting of 2-methyl imidazole, 1-(2-cyanoethyl)-2-alkyl imidazole, 2-phenyl imidazole, and a mixture thereof.

36. The embedded printed circuit board according to claim 33, wherein the inorganic filler is at least any one inorganic material selected from a group consisting of graphite, carbonblack, silica, and clay.

37. The embedded printed circuit board according to claim 31, wherein the photosensitive monomer includes acrylate resin.

38. A method of manufacturing an embedded printed circuit board, comprising:
providing a core layer including a photosensitive composition;
forming a cavity on the core layer by exposure and development processes;
disposing a chip on a copper clad applied with an adhesive layer;
laminating the core layer on the copper clad layer applied with an adhesive layer to mount the chip in the cavity of the core layer;
forming an insulating layer on the core layer mounted with the chip; and
laminating the copper clad layer on the insulating layer and forming a circuit pattern on the copper clad layer.

39. A method of manufacturing an embedded printed circuit board, comprising:
providing a core layer including a photosensitive composition;
forming a cavity on the core layer by exposure and development processes;
disposing a chip on a copper clad applied with an adhesive layer;
laminating the core layer on the copper clad layer applied with the adhesive layer to mount the chip in the cavity of the core layer;
forming an insulating layer made of a photosensitive composition on the core layer mounted with the chip;
forming a via hole on the insulating layer to open a pad of the chip by forming a pattern through the exposure and development processes; and
laminating the copper clad layer on the insulating layer and forming a circuit pattern on the copper clad layer.

40. A method of manufacturing an embedded printed circuit board, comprising:
providing a core layer including a photosensitive composition;
forming a cavity on the core layer by exposure and development processes;
disposing a chip to attach the pad of the chip to an adhesive layer applied with a copper clad;
laminating the core layer on the copper clad layer applied with the adhesive layer to mount the chip in the cavity of the core layer;
forming an insulating layer on the core layer mounted with the chip; and
laminating the copper clad layer on the insulating layer and forming a circuit pattern on the copper clad layer.
